(19) United States
(12) Patent Application Publication
(10) Pub. No.: US 2008/0311739 A1
(43) Pub. Date: Dec. 18, 2008

(54) Method of Forming a Self Aligned Copper Capping Layer

(75) Inventors: Wim Besling, Eindhoven (NL); Thomas Vanypre, Grenoble (FR)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/095,142

(22) PCT Filed: Nov. 27, 2006
(86) PCT No.: PCT/IB2006/054445

§ 371 Date: May 28, 2008

(30) Foreign Application Priority Data
Nov. 28, 2005 (EP) 05300969.2
Nov. 27, 2006 (IB) PCT/IB2006/054445

(51) Int. Cl. H01L 21/4763

(52) U.S. Cl. 438/643; 257/E21.495

(57) ABSTRACT

A method of forming a capping layer on a copper interconnect line (14). The method comprises providing a layer (20) of Aluminium over the interconnect line (14) and the dielectric layer (10) in which it is embedded. This may be achieved by deposition or chemical exposure. The structure is then subjected to a process, such as annealing or further chemical exposure, in an environment containing, for example, Nitrogen atoms, so as to cause indiffusion of Al into the copper line (14) and nitridation to form a diffusion barrier 26 of the intermetallic compound CuAlN.

### FIELD OF THE INVENTION

The invention relates to a method of forming a self-aligned copper capping layer in respect of a copper interconnect layer of a semiconductor device, so as to improve the reliability thereof and to improve capacitive coupling between the lines.

### BACKGROUND OF THE INVENTION

Aluminium has, in the past, been the principal conductive material employed for electrical interconnection in semiconductor devices due to its low resistivity, good adherence to silicon dioxide, low cost, ease in bonding and good etchability. As device geometry continues to scale down for Ultra Large Scale Integrated circuits, there is a growing demand for an interconnect wiring with minimum pitch and high conductivity, while requiring greater levels of reliability. Currently, an integrated circuit is considered good if a test indicates an equivalent life span of 10 years. However, in some specific applications, such as space (e.g. satellite, probe, etc), medical (e.g. pacemakers and the like) and military, a longer life span may be required, so as to avoid, or at least minimize, the requirement for device replacement.

The use of copper interconnect technology is now widely established in the field of advanced, high performance integrated circuit devices. In fact, in many cases, copper has replaced aluminium because of its lower resistivity and higher reliability, which is thought to be because of its higher activation energy for electromigration. Referring to FIG. 1 of the drawings, in a known damascene process for forming copper interconnects, an intrametal dielectric layer 10 (e.g. SiOC) is deposited on a substrate, and patterned and etched to form a trench, leaving a residual hard-mask 11 on the intrametal layer 10 on each side of the trench. Next, a barrier layer 12 is deposited over the structure, following which a copper layer is deposited over the entire structure. The copper is then Chemically Mechanically Polished (CMPd) to leave a copper interconnect line 14 embedded in the intrametal dielectric layer 10. Next, a dielectric barrier or capping layer 16 (e.g. Silicon Nitride, SiN or Silicon Carbide, SiC) is deposited over the copper 14 and intrametal dielectric layer 10 (copper must be surrounded by a barrier to prevent it from diffusing into the surrounding dielectric). The last process step is the deposition of a passivation layer 18.

One of the main phenomena that causes an interconnect layer to degrade is electromigration, in which atoms of the interconnect physically change location as current passes through the interconnect. Electromigration generally is defined as atoms constituting a line that move when current flows into the line due to electrons. Although electromigration resistance of copper is larger than that of aluminium, it will be appreciated that copper will increasingly start to suffer from electromigration reliability issues as geometries continue to shrink and current densities increase. Under high current densities, copper atoms move in the direction of the electron flow, and vacancies accumulate at an interface in the opposite direction into voids that have the effect of increasing circuit resistance and eventually causing an open circuit, which causes the device to fail.

The poor interface 20 between the capping layer 16 (a dielectric) and the interconnect line 14 (a conductor) results in poor adhesion and decreased electromigration resistance. In fact, the poor interface between the copper and the insulative capping layer is responsible for most of the early failures in copper interconnect reliability. Moreover, near the top of the interconnect line 14, the electrical field concentration is largest which enhances local copper migration and stress induced voiding.

Thus, modification of the copper/dielectric interface is required to reduce copper migration and void growth, thereby to extend the viability of copper interconnect technology to smaller dimensions while maintaining high performance and reliability. Several approaches have been proposed for this purpose. Many of them focus on the use of selective deposition techniques, e.g. chemical vapor deposition and electroless deposition, to deposit thin metals, e.g. W, ZrN, CoWB, CoWP on copper after copper Chemical Mechanical Polishing (CMP).

For example, in advanced Cu dual damascene processing, the use of self-aligned barriers (SABs) has been proposed to replace dielectric barrier films used for metal line capping. SABs are mainly applied to improve electromigration resistance and reduce capacitive coupling between adjacent metal lines. Current integration schemes for self-aligned barriers are generally based on a selective, electroless CoWP deposition process, significant improvement in electromigration performance has resulted from implementing these metal cap layers. However, a disadvantage of electroless barriers is that this method faces selectivity issues, since any metallic deposition in between metal lines may degrade leakage current properties, and significant integration development is thought to be required before these barriers can be introduced into standard process flows.

As an alternative, a CuSiN barrier formation method has recently been proposed which is based on copper surface modification, thereby alleviating the above-mentioned selectivity issues while being equivalent in terms of propagation performance to other selectively deposited barrier techniques. Briefly, after cleaning of the upper surface of the copper line, decomposition of silane (SiH₄) is performed and Si is incorporated at the surface to form a copper silicide layer at the upper surface of the interconnect line. Nitrogen incorporation is then effected by applying an NH₃ anneal/plasma to form a CuSiN barrier. In other words, the CuSiN barrier is formed by modifying the surface of the copper interconnect, rather than by a selective deposition technique. However, a disadvantage of this technique is that the resistivity of the interconnect may be increased by an unacceptable amount if the silicidation process (CuSi formation) is not well controlled/halted.

It has been identified that the presence of alloying elements in copper acts to increase electromigration resistivity, because this could pin the Cu atoms in the lattice of an intermetallic compound, and a Cu-alloy capping approach is considered to be very effective in improving reliability. Self-aligned procedures are known for creating a Cu-alloy cap on the upper surface of an interconnect. For example, U.S. Pat. No. 5,447,599 describes a self-aligned process for capping copper lines, wherein after CMP, the lines are coated with titanium (Ti) and subjected to subsequent annealing to create a Cu₃Ti alloy at the copper/titanium junction. The unreacted Ti is stripped away by dry etching, and the remaining Cu₃Ti alloy is subsequently transformed into TiN(O) and copper by Rapid Thermal Annealing (RTA) in an NH₃ atmosphere at a temperature ranging between 550 and 650° C. for around 5 minutes. Thus, the copper lines are capped with a layer of TiN(O) which acts as an effective diffusion barrier. However, in current integration schemes, the anneal temperature is 400° C. maximum (and preferably lower), which is not high enough to create the TiN capping from the intermetallic Cu₃Ti compound. Hence, the resistivity of the interconnect lines will remain too high due to the high resistivity of the Cu₃Ti that remains in the lines.

In fact, a general drawback of alloying copper with other elements is the increase in resistivity. This will become of increasing concern for future technology generations where the copper resistivity starts to increase non-linearly due to electron scattering at grain boundaries and interfaces. Moreover, a smaller copper grain size due to the presence of alloying elements and the presence of impurities on the grain boundaries might also increase the Cu resistivity, pushing the RC delay to unacceptably high levels.

What is actually required is a copper alloy solid solution at the upper surface of the copper lines with very low concentrations of the alloying element, whereby the alloying concentration is sufficiently large to improve on the adhesion but as small as possible to avoid a significant line resistance increase (say, an alloy concentration below 1 at % at the upper interface between the Cu-alloy capping layer and a thin layer of SiCN that prevents diffusion).

US 2004/0207093 A1 describes a method whereby a Cu—Al alloy capping layer is used to improve electromigration behavior by means of a self-aligned indiffusion of aluminium. Starting from the structure following the Chemical Mechanical Polishing step, and referring to FIG. 2a of the drawings, a copper interconnect 14 is embedded within a intrametal dielectric layer 10 with a barrier layer 12 therebetween. A thin metallic Al (or Mg, Zn, etc) film 20 is deposited on top of the metal lines 14 and dielectric layer 10 by, for example, PVD, CVD or ALD, as illustrated in FIG. 2b. The aluminium film 20 is then annealed to form a thin Cu-alloy layer 22 at the top of the interconnect line 14, as illustrated in FIG. 2c. The aluminium 20 that remains after the anneal step (i.e. Cu-alloy formation) is removed by wet or dry chemical etching (see FIG. 2d), and then an AlN, Al₂O₃ or Al₄C₃ film (protection layer) 24 is formed on the top of the interconnect 14 by means of nitridation, oxidation or carbidation of the Cu—Al layer 22, as illustrated in FIG. 2e of the drawings.

However, the process used to form the protection layer implies that there is a sufficient quantity of aluminium in the Cu-alloy to create this layer. Furthermore, the creation of the protection layer requires diffusion of aluminium, and indiffusion may equally occur through the interconnect. These factors, among others, may result in an interconnect resistivity that is too high.

It is preferred to provide a method of forming an interconnect layer for an integrated circuit, whereby reliability is improved without an undue increase in interconnect resistivity.

### SUMMARY OF THE INVENTION

In accordance with the present invention, there is provided a method of forming an interconnect layer for an integrated circuit, the method comprising the steps of:
providing an interconnect line of a first metal in a dielectric layer;
providing a layer of a second metal on a surface of said interconnect line;
performing a process to cause indiffusion of atoms of said second metal into a portion of said interconnect line adjacent said surface and exposing said interconnect line to atoms of a non-metallic substance during said indiffusion process so as to form a diffusion barrier in said portion of said interconnect line adjacent said surface, said diffusion barrier comprising a layer of a compound comprised of said first metal, said second metal and said non-metallic substance.

Thus, the above-mentioned object is achieved by performing a reactive process in respect of the interconnect line and the layer of second metal, in an environment containing atoms of a non-metallic substance, to generate a diffusion barrier of the resultant compound instead of an alloy capping layer, as in the prior art.

In a preferred embodiment of the invention, the first metal comprises copper and the second metal may comprise Aluminium, Magnesium or Boron. These are preferred because they have a much lower resistivity than metals (e.g. Ti, Ta, Cr, Sn) and non-metals (e.g. Si) proposed in the prior art. Also, they react easily with oxygen or nitrogen which are present on the interfaces, thereby improving adhesion and reliability and preventing excessive indiffusion of the second metal into the first metal. Furthermore, Al and Mg are soluble in copper to a relatively small extent and do not create highly resistive intermetallic compounds.

The non-metallic substance preferably comprises one or more of nitrogen, oxygen or carbon, such that exposure of said interconnect line and layer of second metal thereto during said diffusion process causes nitridation, oxidation or carbidation respectively. Thus, in one exemplary embodiment, the first metal comprises Copper, the second metal comprises Aluminium and the non-metallic substance comprises nitrogen, such that the resultant diffusion barrier comprises a Cu—AlN compound.

Beneficially, the layer of said second metal is provided by means of a deposition process, such as PVD, CVD or ALD. Preferably, the layer of second metal is deposited on the surface of the interconnect line and the adjacent dielectric layer.

The interconnect line may be subjected to an annealing process at a relatively low temperature in a plasma environment, thereby avoiding massive indiffusion of the second metal into the body of first metal, or it may be subjected to annealing at a relatively higher temperature (using a furnace or heated chuck, for example) in a reactive environment.

In a first exemplary embodiment of the invention, the interconnect line and layer of said second metal is subjected to a reactive annealing process in an environment containing said non-metallic substance, so as to cause indiffusion of atoms of the second metal into the interconnect line and create an alloyed layer at the surface of the interconnect line, which alloyed layer reacts with the atoms of the non-metallic substance to form the diffusion barrier. The reaction with the atoms of the non-metallic substance to form the above-mentioned compound has the advantage of pinning the second metal in the matrix of the first metal (to prevent further indiffusion thereof into the interconnect line). The reactive atmosphere during the annealing process may typically comprise N₂/H₂, NH₃, or N₂) plasma or a furnace anneal in an ammonia environment. In the case where the layer of said second metal is deposited additionally on the surface of the dielectric layer, the reaction with the atoms of the non-metallic substance causes the portions of the layer of second metal on the dielectric to be transformed to an insulative compound of said second metal, which has the additional advantage of preventing inter-metal line leakage. This insulative compound may (optionally) be subsequently removed by, for example, wet chemical or etch stripping means (e.g. chloride based chemistries). However, if it is not removed, it can act as a diffusion barrier and etch stop layer for the interconnect layer above.

In a second exemplary embodiment of the invention, the interconnect line may be subjected to a chemical exposure with gaseous precursors that contain atoms of said second metal, e.g. a trimethyl aluminium (TMA) vapor treatment. The gaseous precursor will decompose on the surface of the interconnect line leaving a layer of atoms of said second metal behind. In a preferred embodiment, the precursor may be sequentially supplied in a manner similar to ALD (Atomic Layer Deposition) with a compound containing atoms of the non-metallic substance, e.g. NH₃, as co-reactant. In this manner, a dielectric film comprising a compound of the second metal and the non-metallic substance can be grown on the interconnect line (and the dielectric layer) and, during this process, the second metal that is deposited during the initial cycle will react with the co-reactant to form the diffusion barrier on the interconnect layer, thereby improving adhesion. This chemical approach is considered to effectively control the dose of the second metal and the degree of alloying of the portion of the interconnect layer adjacent the above-mentioned surface. The dielectric film thus formed, which covers the dielectric layer and the diffusion barrier, acts as an etch stop layer for subsequent interconnect layers, on which etch stop layer can be deposited the next layer of ULK material.

It will be appreciated that the interconnect line may be exposed to a combination of oxygen and nitrogen atoms during the indiffusion process.

The present invention extends to a method of manufacturing an integrated circuit comprising one or more semiconductor devices, the method comprising providing a dielectric layer on a substrate, providing an interconnect line of a first metal in said dielectric layer, providing a layer of a second metal on a surface of said interconnect line, performing a process to cause indiffusion of atoms of said second metal into a portion of said interconnect line adjacent said surface and exposing said interconnect line to atoms of a non-metallic substance during said indiffusion process so as to form a diffusion barrier in said portion of said interconnect line adjacent said surface, said diffusion barrier comprising a layer of a compound comprised of said first metal, said second metal and said non-metallic substance.

The present invention also extends to an integrated circuit manufactured by the method defined above,

These and other aspects of the present invention will be apparent from, and elucidated with reference to, the embodiments described herein.

Embodiments of the present invention will now be described by way of examples only and with reference to the accompanying drawings.

### BRIEF DESCRIPTION OF THE DRAWINGS

FIG. 1 is a schematic cross-sectional view of a metal interconnect structure according to the prior art;

FIGS. 2a to 2e illustrate schematically the principal steps of a method according to the prior art for forming a Cu—Al alloy capping layer on a copper interconnect;

FIGS. 3a to 3d illustrate schematically the principal steps of a method according to a first exemplary embodiment of the present invention for forming a capping layer on a copper interconnect; and

FIGS. 4a to 4d illustrate schematically the principal steps of a method according to a second exemplary embodiment of the present invention for forming a capping layer on a copper interconnect.

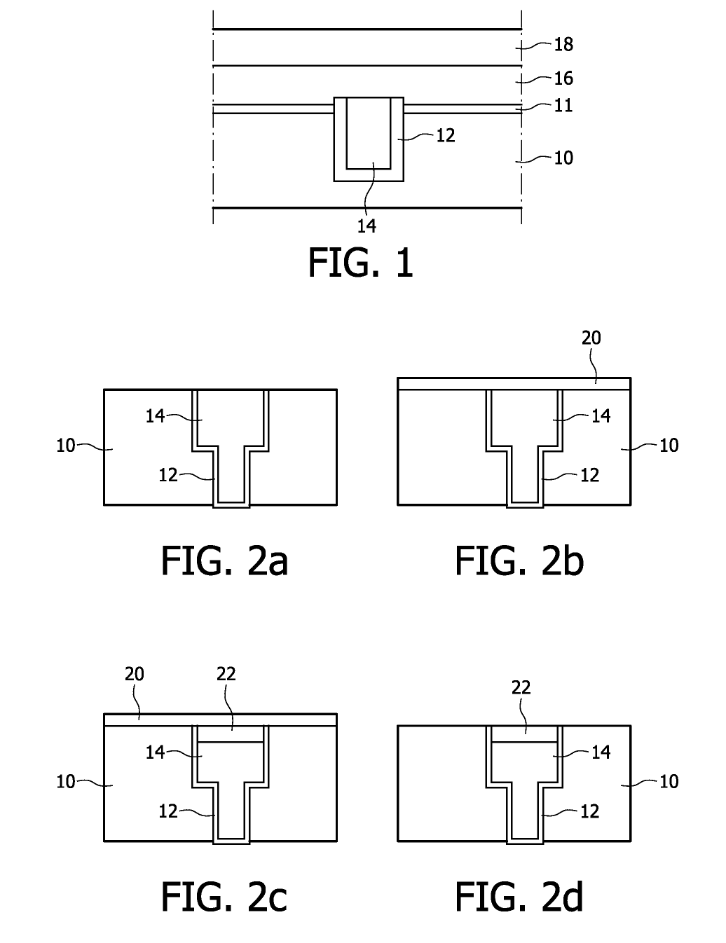

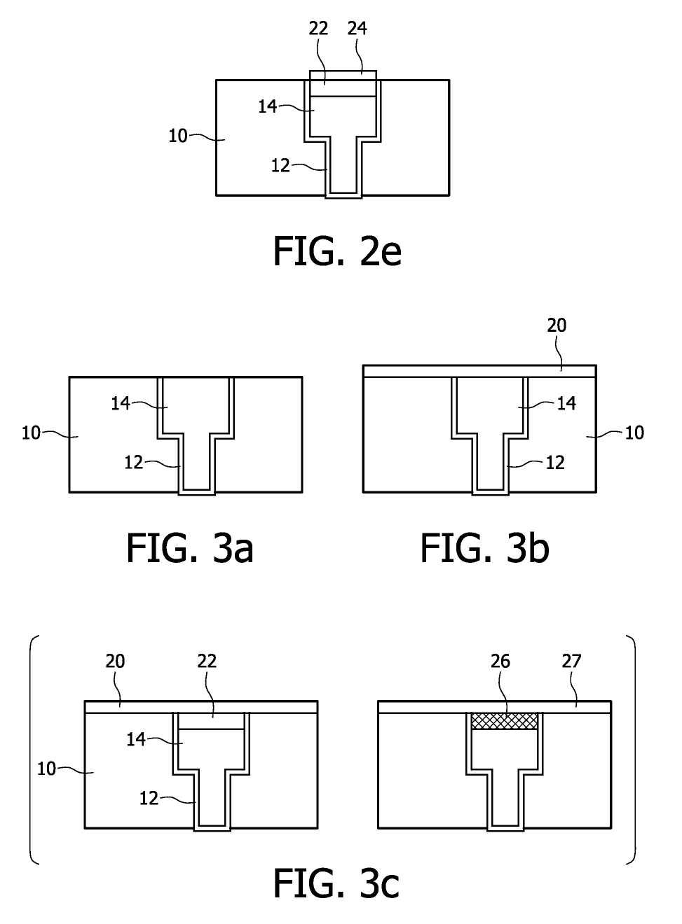

### DETAILED DESCRIPTION OF EMBODIMENTS

A process is thus proposed herein for the formation of a self-aligned Cu-alloy capping layer on a metal interconnection that has improved adhesion properties and resistance to electromigration and stress-induced voiding near the upper part of the interconnect lines. This is achieved by forming an intermetallic compound, for example, a copper alloyed compound (e.g. CuAlN) near the top of the interconnect lines. Thus, the indiffusion of aluminium into the copper can be controlled.

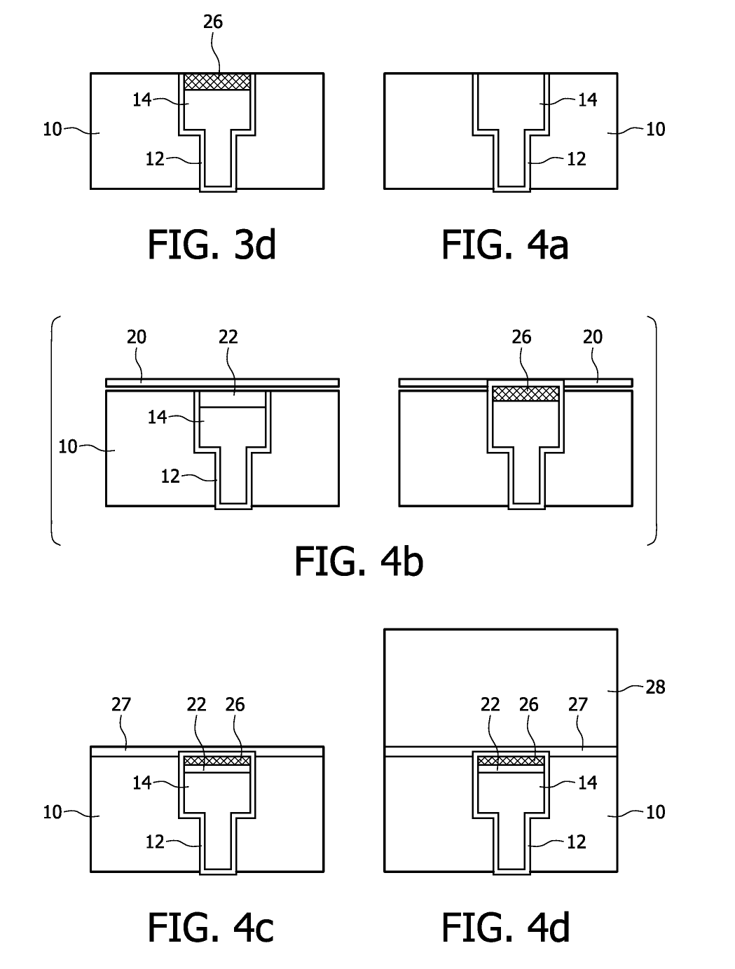

Starting from the structure following the Chemical Mechanical Polishing step, and referring to FIGS. 3a and 4a of the drawings, a copper interconnect 14 is embedded within a intrametal dielectric layer 10 with a barrier layer 12 therebetween. In a first exemplary embodiment of the present invention, a thin metallic Al (or Mg, B, Zn, etc) film 20 is deposited on top of the metal lines 14 and dielectric layer 10 by, for example, PVD, CVD or ALD, as illustrated in FIG. 3b. Next, and as illustrated in FIG. 3c, a reactive annealing process is performed in an ammonia environment, or nitrogen or oxygen or carbon-containing plasma so to create a very thin Cu—Al alloyed layer 22 at the top of the interconnect line 14 in respect of which nitridation/oxidation/carbidisation occurs to pin the Al in the copper matrix and create the CuAlN diffusion barrier 26. The remaining aluminium (on the dielectric layer 10) is transformed into AlN, Al₂O₃ Al₄C₃, or a mixture thereof: AlNxOy (27), which prevents inter-metal line leakage. The nitrogen and oxygen-containing AlNₓO_{y} layer 27 may (optionally) be removed by wet chemical or etch stripping means (e.g. chloride based chemistries), as illustrated in FIG. 3d of the drawings.

It will be appreciated that it is desirable to minimise aluminium diffusion in copper and, therefore, the temperature budget and anneal time should be kept low. However, when aluminium is brought into direct contact with the copper and subsequently annealed, the aluminium indiffusion into the copper bulk has been found to be unacceptably high, even at relatively low anneal temperatures, and cannot be adequately controlled. Therefore, nitridation/oxydation of the aluminium is performed to transform the metallic film into a dielectric material, thereby preventing further indiffusion and solving the above-mentioned problem. The Al is thus fixed/bonded on top of the copper lines. In this case, it is not absolutely necessary to remove aluminium in between lines as an AlNₓO_{y} film is non-conductive. As Al is quickly passivated by a hermetic oxide film, the Al film should be deposited as thin as possible to allow complete oxidation (say, 2 nm maximum).

Thus, in summary, in a method according to a first exemplary embodiment of the present invention, a thin metallic Al (or Mg or B) film is deposited by means of, for example, PVD, CVD, ALD, Plasma enhanced ALD or ion induced ALD on top of metal lines and dielectric. A reactive anneal is carried out form a copper-alloyed compound (e.g. CuAlN) near the top of the metal lines. Excessive Al indiffusion of Al degrades Cu resistivity and, therefore, it is an advantage of the present invention that the indiffusion of Al can be controlled by forming this intermetallic compound near the upper interface. The reactive atmosphere during the anneal might typically be N₂/H₂, NH₃ or N₂O plasma anneal or a furnace anneal in an ammonia environment. Due to the reactive anneal, a dielectric AlN, Al₂O₃ or AlNₓO_{y} film is formed in between the metal lines, while a CuAlN or CuAlN(O) film is formed on top of the lines with a very shallow diffusion profile. The dielectric AlN, Al₂N₃ or AlNₓO_{y} based film can be removed by wet chemical means or by dry etching. The CuAlN will have a lower etch rate than the AlN on Al₂O₃ or AlNₓO_{y} dielectric capping and will therefore remain at the interface. If the AlN, Al₂O₃ or AlNₓO_{y} capping is not removed, it will act as a diffusion barrier and etch stop layer for an interconnect layer above.

In a second exemplary embodiment of the present invention, and referring to FIG. 3b of the drawings, the interconnect line 14 is subjected to chemical exposure with gaseous precursors that contain, say, aluminium, e.g. a trimethyl aluminium (TMA) vapor treatment. The TMA will decompose on the copper surface, leaving a layer 20 of Al atoms behind. The TMA can then be sequentially supplied in an ALD type fashion with, for example, NH₃ as co-reactant, such that the Al that was deposited during the initial cycle diffuses into the copper and reacts with NH₃ to form CuAlN 26, thereby improving adhesion at the interface with the interconnect 14.

By way of background, and as opposed to conventional CVD which is characterized by continuous deposition and concurrent flow of precursors, Atomic Layer Deposition (ALD) is based on the sequential deposition of individual monolayers or fractions of a monolayer in a well controlled manner. In ALD, the growth surface is alternately exposed to only one of two complementary chemical environments, i.e. individual precursors are supplied to the reactor one at a time. Exposure steps are separated by inert gas purge or pump-down steps in order to remove any residual chemically active source gas or by-products before another precursor is introduced into the reactor. Thus, ALD consists of a repetition of individual growth cycles. Each cycle is made up of a typical sequence: Flow of precursor 1 ‘Purge’ Flow of Precursor 2 ‘Purge. During each exposure step, precursor molecules react with the surface until all available surface sites are saturated. Precursor chemistries and process conditions are chosen such that no further reaction takes place once the surface is completely saturated. Surface saturation guarantees the self-limiting nature of ALD.

This chemical approach can be used in an exemplary embodiment of the present invention to effectively control the dose of Al and the degree of alloying of the top layer. The resultant structure is illustrated in FIG. 3c, which shows the interconnect line 14 embedded in the intrametal dielectric layer 10 with a Cu—Al alloyed layer 22 close to the top of the interconnect and capped with a layer 26 of CuAlN, with a dielectric layer 27 of AlN provided over the capping layer 26 and the intrametal dielectric layer 10. This dielectric layer 27 provides a diffusion barrier and etch stop in respect of the interconnect layer above, the ULK intrametal dielectric layer 28 of which is shown in FIG. 4d deposited over the dielectric AlN layer 27.

In general, the advantages of the above-described exemplary embodiments of the present invention include adhesion improvement with the dielectric at the top interface of the copper line, and localized grain stuffing of copper lines with aluminium and nitrogen that pins the copper and suppresses copper migration and void formation and improves electromigration performance. Further more, because the indiffusion of Al into the copper interconnect is limited, the resistivity of the copper line is not significantly degraded. Instead of creating the Cu-alloy first by indiffusion and removing the metal layer (e.g. Ti or Al) by etch strip and then transforming the copper alloy into a metallic TiN or dielectric AlN or Al₂O₃ cap, as in prior art proposals, the capping metal is instead nitrided and/or oxidised in a reactive indiffusion (e.g. annealing) step to create an intermetallic compound on top of the lines (in the above, CuAlN or CuAlN(O) capping). The in-situ nitridation during, for example, anneal avoids undesirable diffusion of the Al into the copper, i.e. it keeps the alloying element as close as possible to the interface.

In summary the novel approach proposed by the present invention achieves five significant goals:
1. Create a CuAlN diffusion barrier on top of the line instead of a Cu—Aluminium alloy only, as in prior art proposals;
2. Limit the indiffusion of Al into the copper bulk by letting it react in an early phase with a nitrogen containing precursor in order to avoid line resistance degradation;
3. Reduce temperature budget by performing in one exemplary embodiment, an anneal and the nitridation in one step;
4. Reduction of process steps i.e. process time/process complexity; and
5. Improvement of adhesion, copper electromigration and copper diffusion barrier properties due to the formation of actual chemical covalent bonds instead of intermetallic bonds of a CuAl alloy.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

A person skilled in the art will readily appreciate that various parameters disclosed in the description may be modified and that various embodiments disclosed may be combined without departing from the scope of the invention.

It is stipulated that the reference signs in the claims do not limit the scope of the claims, but are merely inserted to enhance the legibility of the claims.

1. A method of forming an interconnect layer for an integrated circuit, the method comprising the steps of:
providing an interconnect line of a first metal in a dielectric layer;
providing a layer of a second metal on a surface of said interconnect line;
performing a process to cause indiffusion of atoms of said second metal into a portion of said interconnect line adjacent said surface and exposing said interconnect line to atoms of a non-metallic substance during said indiffusion process so as to form a diffusion barrier in said portion of said interconnect line adjacent said surface, said diffusion barrier comprising a layer of a compound comprised of said first metal, said second metal and said non-metallic substance.

2. A method according to claim 1, wherein said first metal comprises copper and the second metal comprises Aluminium, Magnesium or Boron.

3. A method according to claim 1, wherein said non-metallic substance comprises nitrogen, oxygen or carbon, such that exposure of said interconnect line and layer of second metal thereto during said annealing process causes nitridation, oxidation or carbidation respectively.

4. A method according to claim 1, wherein said layer of second metal is deposited on the surface of the interconnect line and the adjacent dielectric layer.

5. A method according to claim 1, wherein the interconnect line and layer of said second metal is subjected to a reactive annealing process in an environment containing said non-metallic substance, so as to cause indiffusion of atoms of the second metal into the interconnect line and create an alloyed layer at the surface of the interconnect line, which alloyed layer reacts with the atoms of the non-metallic substance to form the diffusion barrier.

6. A method according to claim 5, wherein said annealing process is performed at a relatively low temperature in a plasma environment.

7. A method according to claim 6, wherein said annealing process is performed at a relatively high temperature in a reactive environment.

8. A method according to claim 5, wherein the layer of said second metal is deposited additionally on the surface of the dielectric layer, and the reaction with the atoms of the non-metallic substance causes the portions of the layer of second metal on the dielectric to be transformed to an insulative compound of said second metal.

9. A method according to claim 1, wherein the interconnect line is subjected to a chemical exposure with gaseous precursor that contain atoms of said second metal, wherein said gaseous precursor decomposes on the surface of the interconnect line leaving said layer of said second metal behind.

10. A method according to claim 9, wherein said precursor is sequentially supplied with a compound containing atoms of said non-metallic substance as co-reactant.

11. A method according to claim 9, wherein a dielectric layer is formed over said interconnect line and said dielectric layer during said chemical exposure.

12. A method of manufacturing an integrated circuit comprising one or more semiconductor devices, the method comprising the method as claimed in claim 1.

13. A method of manufacturing an integrated circuit comprising one or more semiconductor devices, the method comprising providing a dielectric layer on a substrate, providing an interconnect line of a first metal in said dielectric layer, providing a layer of a second metal on a surface of said interconnect line, performing a process to cause indiffusion of atoms of said second metal into a portion of said interconnect line adjacent said surface and exposing said interconnect line to atoms of a non-metallic substance during said indiffusion process so as to form a diffusion barrier in said portion of said interconnect line adjacent said surface, said diffusion barrier comprising a layer of a compound comprised of said first metal, said second metal and said non-metallic substance.

14. A method as claimed in claim 13, wherein a portion of the layer of the second metal not covering the interconnect is removed.

15. A method as claimed in claim 14, wherein the portion of the layer of the second metal is removed after the exposure to the atoms of a non-metallic substance.

16. A method as claimed in claim 13, wherein the layer of the second metal after the exposure to the atoms of a non-metallic substance is used as an etch-stop layer.

17. An integrated circuit manufactured by the method of claim 13.

18. An integrated circuit comprising an interconnect line of a first metal in a dielectric layer, and having a diffusion barrier at a surface portion of said interconnect line, said diffusion barrier comprising a layer of a compound comprised of said first metal, a second metal and a non-metallic substance.
